(19) United States
(12) Patent Application Publication
(10) Pub. No.: US 2026/0016556 A1
(43) Pub. Date: Jan. 15, 2026

(54) LINEAR MAPPING B1 CORRECTION FOR MAGNETIC RESONANCE FINGERPRINTING

(71) Applicant: The Cleveland Clinic Foundation, Cleveland, OH (US)

(72) Inventors: Brendan Lee Eck, Cleveland Heights, OH (US); Xiaojuan Li, Beachwood, OH (US); Jeehun Kim, Shaker Heights, OH (US); Stefan Zbyn, Beachwood, OH (US); Mingrui Yang, Beachwood, OH (US)

(21) Appl. No.: 19/266,500

(22) Filed: Jul. 11, 2025

Related U.S. Application Data
(60) Provisional application No. 63/669,721, filed on Jul. 11, 2024.

(51) Int. Cl. G01R 33/565; G01R 33/44; G01R 33/48; G01R 33/56

(52) U.S. Cl. CPC G01R 33/56572; G01R 33/443; G01R 33/4828; G01R 33/5608

(57) ABSTRACT

A magnetic resonance fingerprint (MRF) method includes obtaining an MRF undersampled image, and determining a corresponding radiofrequency transmit magnetic field strength for a pixel of the image. The method also includes obtaining a tissue property from an MRF dictionary based on the pixel, and correcting the tissue property based on the determined radiofrequency transmit magnetic field strength. According to another aspect, a MRF method includes generating a full MRF dictionary based on a nominal radiofrequency transmit magnetic field strength and, for each of a plurality of radiofrequency transmit magnetic field strengths different than the nominal field strength, subsampling the full MRF dictionary and generating a corrected MRF dictionary based on the subsampled dictionary and the different field strengths. The method also includes determining a transformation matrix between the full MRF dictionary and each of the corrected MRF dictionaries.

### CROSS REFERENCE TO RELATED APPLICATIONS

The application claims priority to and the benefit of U.S. Provisional Patent Application No. 63/669,721, filed on Jul. 11, 2024, entitled “LINEAR MAPPING B1 CORRECTION FOR MAGNETIC RESONANCE FINGERPRINTING”, the entirety of which is incorporated herein by reference.

### STATEMENT OF GOVERNMENT-SPONSORED RESEARCH

This invention was made with government support under AG070321 awarded by the National Institutes of Health. The government has certain rights in the invention.

### BACKGROUND

In a strong magnetic field such as those used in MRI, tissues have characteristic magnetic properties that can be probed in order to assess their composition. Magnetic Resonance Fingerprinting (MRF) is a Magnetic Resonance Imaging (MRI) based method that provides quantitative values of those tissue properties in a single scan. More particularly, MRF uses a physical model to generate a dictionary of possible MRI signal evolutions in response to acquisition parameters, which are then compared to measured MRF data to yield reconstructed tissue property maps. MRF can provide quantitative maps for multiple parameters (e.g., T1, T2, T2*, T1rho, Fat Fraction) from a single acquisition, rather than requiring separate acquisitions for each parameter. Accordingly, MRF permits rapid, simultaneous quantification of multiple tissue properties.

However, MRF can exhibit errors due to inhomogeneity of the radiofrequency transmit magnetic field (B1) when system imperfections are not accounted for. While nominal relative B1 is assumed to have value of B1=1 in traditional MRF dictionaries, there is a known variation of B1 field in practice (e.g., range of 0.5 to 1.5). These errors can be particularly prevalent at high flip angles and at ultrahigh field (e.g., 7 T).

FIG. 1 illustrates a conventional technique 100 in which only a single B1 value, such as a nominal value of B1=1 is considered. In this regard, a pattern matching process 102 compares a measured time-domain signal of each pixel or voxel in corresponding MRF image data 104 to time-domain signals stored in a dictionary 110. In the pattern matching process 102, the best match providing tissue property values are then assigned to a same spatial location in associated tissue property maps 112. As suggested, such measurements and determinations may be sufficient if B1 variations are not present; however, quantitative values will be biased if there is B1 variation.

Such errors are conventionally accounted for by building B1 into the MRF dictionary 110. However, this approach comes at significant computational and memory cost, because the MRF dictionary 110 has a size that increases exponentially with each additional parameter or tissue property. For example, for a dictionary having 100 entries for each parameter, a 3-parameter dictionary has a size of 1 million entries, while a 4-parameter dictionary has a size of 100 million entries. Thus, the MRF dictionary 110 becomes prohibitively large at four or more parameters. This computational complexity slows the investigation of MRF technique designs as well as limits the reach of the technology due to the need for strong computing power that is often only available to research institutions.

FIG. 2 illustrates an example conventional technique 200 in which a B1 map 202 has been collected and can be used to correct for field variations. In this case, each pixel 210 or voxel in MRF image data 204 has a corresponding B1 value 212 on the B1 map 202. A dictionary 214 contains varied B1 values, and a corresponding portion 220 of the dictionary 214 with a same B1 value as the MRF image data 204 is used in a pattern matching process 222. In other words, the dictionary 214 contains subsets of entries with different B1 values. Since the B1 value for a given pixel is known from the B1 map 202, that pixel is pattern matched only to those entries in the dictionary 214 that have the closest B1 value. This process is performed separately for each pixel. Such a technique can provide B1-corrected tissue property maps (value is assigned at same location, circled), but as suggested above, requires a significantly larger dictionary for effective use. This large dictionary mostly goes unused for each spatial location's pattern matching step. In the pattern matching process 222, determined best match tissue property values may be assigned to a same spatial location in associated tissue property maps 224.

As a whole, current methods for addressing B1 variance are prohibitively time consuming and/or sacrifice the precision of estimated B1 values, leading to bias or imprecision in downstream MRF-based quantification of parameters and/or tissue properties.

### BRIEF SUMMARY

According to an aspect, a magnetic resonance fingerprint (MRF) method includes obtaining an MRF undersampled image, and determining a corresponding radiofrequency transmit magnetic field strength for a pixel of the image. The method also includes obtaining a tissue property from an MRF dictionary based on the pixel, and correcting the tissue property based on the determined radiofrequency transmit magnetic field strength.

According to another aspect, a MRF method includes generating a full MRF dictionary based on a nominal radiofrequency transmit magnetic field strength and, for each of a plurality of radiofrequency transmit magnetic field strengths different than the nominal field strength, subsampling the full MRF dictionary and generating a corrected MRF dictionary based on the subsampled dictionary and the different field strengths. The method also includes determining a transformation matrix between the full MRF dictionary and each of the corrected MRF dictionaries.

A method for correcting B1 inhomogeneity in MRF is disclosed, utilizing a linear mapping approach to efficiently incorporate measured B1 variations into quantitative tissue property mapping. The innovation described herein includes a process in which a nominal MRF dictionary is generated and subsampled, with additional dictionaries created at varied B1 values and linear transformation matrices computed between them. The method enables precise B1 correction for each pixel or voxel by interpolating between stored linear mappings based on measured B1 values, significantly reducing computational complexity and memory requirements compared to conventional approaches. The innovation described herein provides improved accuracy in tissue property estimation, facilitates rapid image reconstruction, and supports integration into clinical and research imaging protocols, thereby expanding the practical utility and accessibility of quantitative MRI techniques.

### BRIEF DESCRIPTION OF THE SEVERAL VIEWS OF THE DRAWING

FIG. 1 illustrates MRF pattern matching-based reconstruction to obtain tissue property maps without B1 correction.

FIG. 2 illustrates MRF pattern matching-based reconstruction to obtain tissue property maps with the use of prior knowledge of the B1 map.

FIG. 3 illustrates a flow chart of an example linear mapping B1 correction method for MRF and its incorporation into the MRI data acquisition, processing, and interpretation systems according to the present disclosure.

FIG. 4 illustrates MRF pattern matching-based reconstruction to obtain tissue property maps with the prior knowledge of a B1 map as well as a linear mapping applied to a dictionary based on a nominal B1 value.

FIG. 5 illustrates an example linear mapping B1 correction for an MRF dictionary.

FIG. 6 shows example simulated MRF signals from a nominal dictionary with B1=1 and a target dictionary with B1=0.8.

FIG. 7 shows example simulated MRF signals from a nominal dictionary after application of linear mapping B1 correction and a target dictionary with B1=0.8.

FIGS. 8A and 8B show a comparison of MRF signals at uniform B1=0.8 and nonuniform B1 with mean B1=0.8.

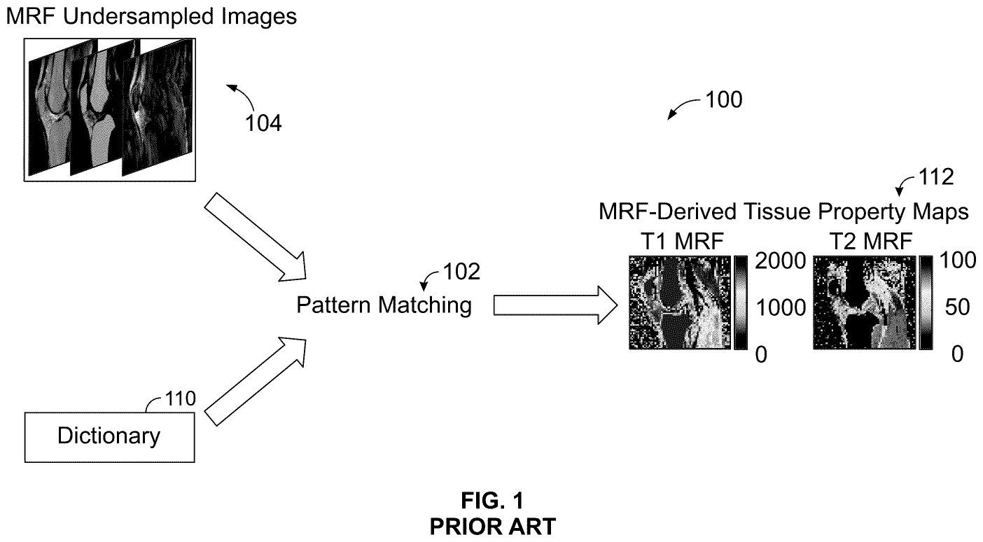

### DETAILED DESCRIPTION

Based on the foregoing, the present disclosure relates to an MRF technique that reduces computational requirements without sacrificing B1 precision in corrections. This technique relies on acquired B1 values rather than being limited to pre-defined B1 dictionary entries, and can reduce MRF dictionary generation time and computational requirements, facilitating inclusion in more clinical and research imaging protocols. As a result, the methods and systems of the present disclosure may expand the range of data that can be collected in vivo by magnetic resonance (MR) systems, and can be incorporated into research or clinical imaging protocols on human or animal magnetic resonance imaging (MRI) scanners.

Briefly, the method and systems described herein use an MRF dictionary generation and correction procedure that integrates data collection and quantitative image reconstruction. The technique relies on linearly mapping B1 information to the MRF dictionary in a manner that is straightforward and directly interpretable to incorporate measured B1 information into the MRF dictionary for quantitative image reconstruction. As such, an MRF dictionary may be derived for a nominal B1=1 value. A correction, which is a linear mapping, to the dictionary may then be determined for each of a plurality of other B1 values. For a measured B1 value, the dictionary may then be appropriately corrected, for example, according to the determined linear mapping. In instances where a correction has not previously been determined for a given B1 value, the appropriate linear mapping correction may be interpolated or otherwise estimated, for example, based on the determined corrections for the closest B1 values.

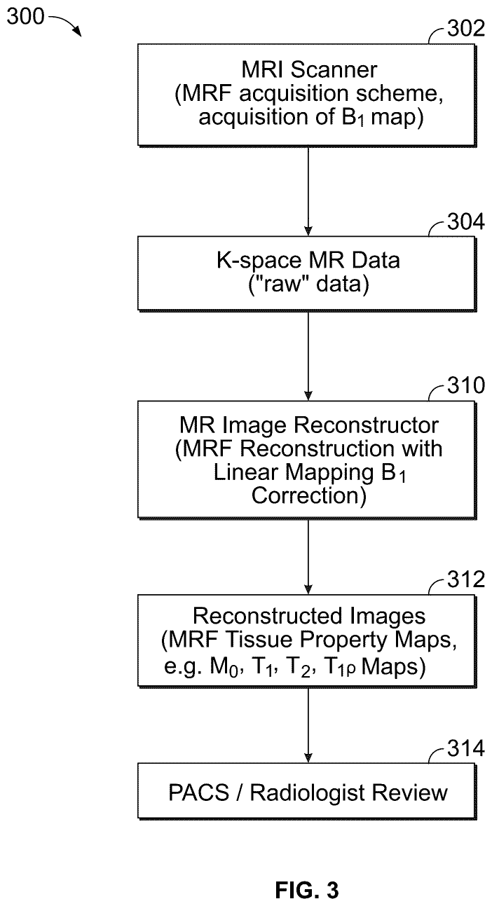

Referring to FIG. 3, an example linear mapping B1 correction method 300 for magnetic resonance fingerprinting (MRF) is illustrated according to an exemplary embodiment. FIG. 3 is described in connection with MRI data acquisition, processing, and interpretation systems, and may be understood in view of the system configurations described elsewhere in this application. For clarity, the method 300 is presented as a sequence of steps, but the steps may be performed in a different order, grouped into sub-processes, or implemented concurrently in other embodiments.

At block 302, the method 300 includes using an MRI scanner to acquire MRF data associated with a subject. The data acquisition corresponds to an MRF dictionary that includes tissue-specific signal evolutions, which are generated from a physics-based model of tissue relaxation and excitation dynamics. The MRF dictionary provides reference tissue “fingerprints” used to interpret the acquired MRF signal. The signal evolutions are dependent, in part, on nominal B1 values, and the method includes correcting the MRF dictionary based on measured B1 inhomogeneities using a linear mapping technique.

The dictionary may be generated assuming a homogeneous B1 field with a nominal B1 value of 1. Additionally, the MRI scanner may collect B1 mapping data, from which maps of relative B1 values (e.g. 0 to 2) are determined. In embodiments, the method 300 generates dictionary entries for a sub-sampled space of the nominal MRF dictionary at different B1 values.

At block 304, the method 300 includes reconstructing MRF images from k-space MR data acquired by the MRI scanner. The acquired k-space data represents frequency-domain signals corresponding to spatially encoded MRF measurements. Using a suitable reconstruction technique—such as iterative low-rank reconstruction or other image-domain transformations—the method 300 converts the k-space data into time-resolved MRF undersampled images suitable for subsequent dictionary matching. In some embodiments, compression and decompression of the MRF data may be applied to reduce memory usage during reconstruction and enable integration of B1 correction in an uncompressed domain.

At block 310, the method 300 includes determining and storing linear mappings from the nominal B1 dictionary to other B1 values. In one example, the linear mappings may be between the nominal B1=1 dictionary and dictionaries of varied B1 values such as, for example, B1=0.5 to B1=1.5 at a ΔB1=0.2 spacing. At block 312, the method 300 includes using the acquired B1 map to perform a linear mapping of the nominal dictionary to that of the measured B1 value for a given image location. Depending on the embodiment, the B1 value may be obtained by using a weighted sum such as, for example, a linear interpolation of the previously computed linear mappings. With this construction, the method 300 applies a modified image reconstruction procedure.

At block 314, the reconstructed tissue property maps, such as, for example and without limitation T1, T2, and T1p maps, are transmitted to a picture archiving and communication system (PACS) for storage, access, and clinical integration. These maps may then be reviewed by a radiologist or other medical professional to support diagnostic interpretation, treatment planning, or research analysis. This PACS/radiologist review step at block 314 effectively incorporates the B1-corrected MRF data produced by the method 300 into a clinical workflow.

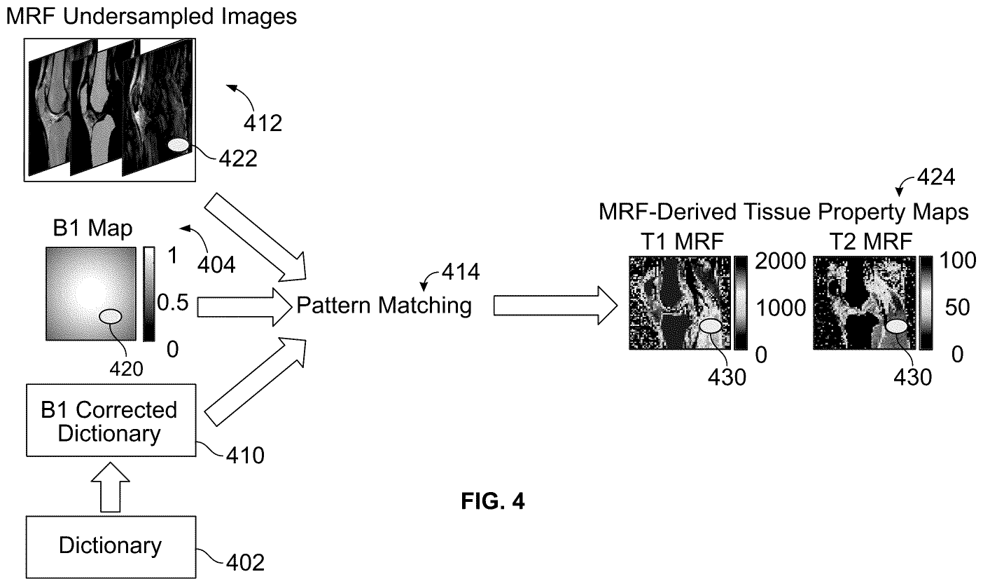

FIG. 4 illustrates a linear mapping B1 correction process 400 that may be used in the method 300 of FIG. 3. With reference to FIG. 4, a dictionary 402 may be a same size as the dictionary of the method 300 shown in FIG. 3, but undergoes a linear mapping to the B1 value based on each pixel location and prior knowledge from a B1 map 404. In other words, the dictionary values associated with the nominal B1 value (e.g., B1=1) are corrected according to one or more predetermined linear mappings, resulting in a B1 corrected dictionary 410. Then, MRF undersampled image data 412, which may be signal evolution data, is pattern matched in a pattern matching process 414 to the appropriate B1 corrected dictionary 410. Separate B1 correction may be performed for each pixel 420 or voxel in the B1 map 404 based on a corresponding pixel 422 or voxel in the MRF undersampled image data 412, producing B1 corrected tissue property maps 424 with a corresponding corrected pixel 430 or voxel.

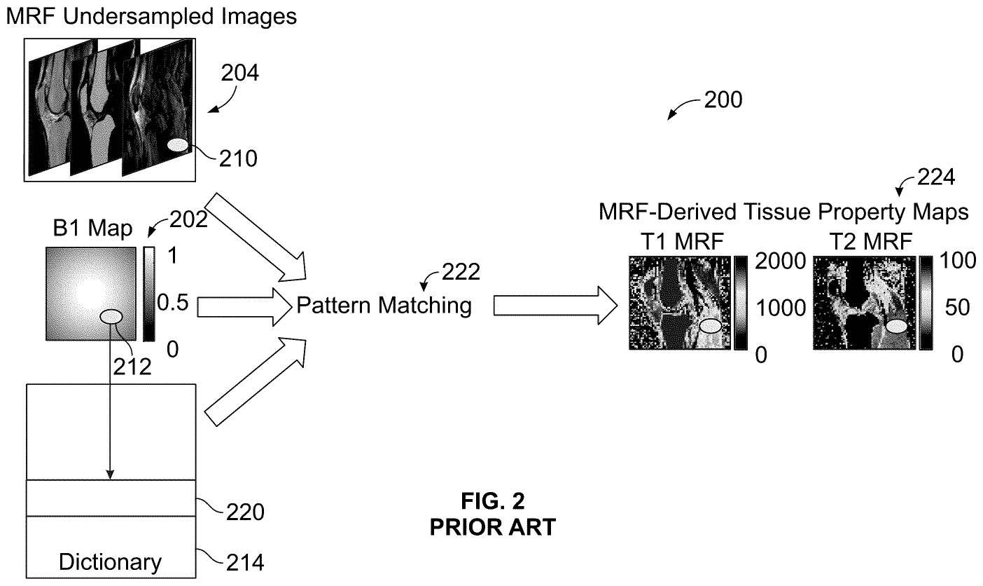

With this construction, the method 300, including the linear mapping B1 correction process 400, avoids relatively large dictionary computation while still correcting for B1 variation. As such, rather than generating a relatively large dictionary, the method 300 described herein uses a linear mapping from the nominal B1 valued dictionary to the target B1 valued dictionary, where the target B1 value for the linear mapping correction is based on the B1 map. The linear mappings are stored on a memory for use in this correction, but require less additional memory in a computing system as compared to the nominal, uncorrected case. Furthermore, such memory cost is of a substantially lesser size in total as compared to a full dictionary that includes B1 combinations as shown in FIG. 2.

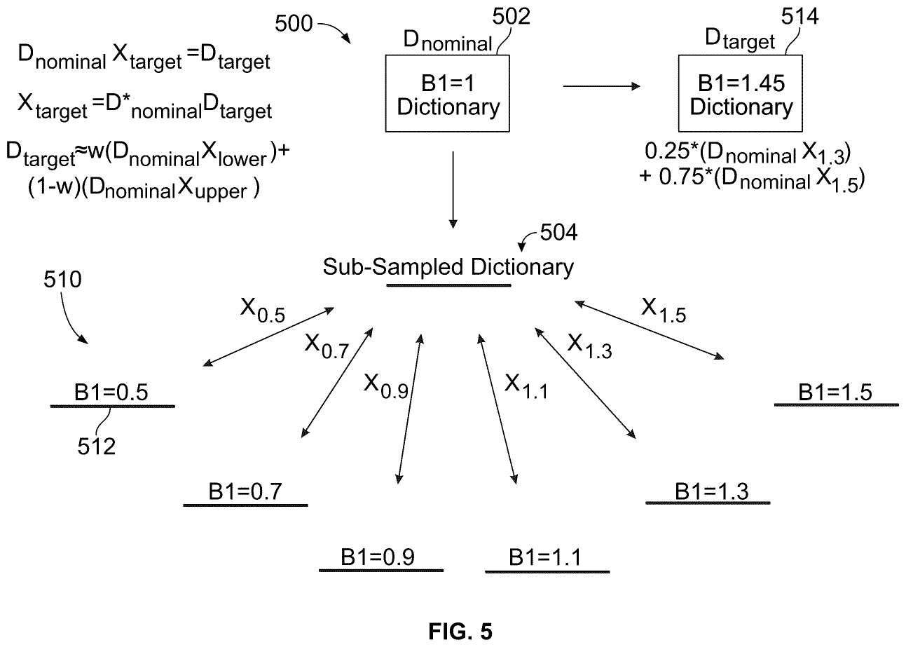

FIG. 5 illustrates an example process 500 of linear mapping B1 correction for an MRF dictionary that may be employed in the method 300 of FIG. 3. As shown in FIG. 5, the process 500 starts with a known, nominal dictionary 502 at B1=1.0. The nominal dictionary 502 is subsampled (e.g., at 8x subsampling) to produce a smaller subsampled dictionary 504 also at B1=1.0. Other additional dictionaries 510 of the same tissue property combinations as the subsampled dictionary 504 are generated at varied B1 values 512 (e.g. with ΔB1=0.2 such that B1=0.5, B1=0.7, B1=0.9, B1=1.1, B1=1.3, B1=1.5).

The transformation from the nominal dictionary 502, expressed as Dnominal, to a target dictionary 514, expressed as Dtarget, is performed using a linear mapping, Xtarget. This Xtarget may be computed for each of the other dictionaries 510 for the B1 values 512 different than the nominal dictionary 502 where B1=1. In this regard, the linear mapping Xtarget may be computed via pseudoinversion of the subsampled dictionary 504 that is multiplied by the target dictionary 514. Mapping matrices may be stored in a memory of a computer system for use in the B1 correction MRF reconstruction. Precise B1 corrections, rather than coarse quantization of possible B1 correction values, may be obtained by linearly combining or interpolating known X mappings.

According to one particular example, the model is based on the relationship:

$${D}_{nominal} {X}_{target} = {D}_{t a r g e t} \qquad ( Equation l )$$

which can be solved as:

$${X}_{target} = D {*}_{nominal} {D}_{target} \qquad ( Equation 2 )$$

where D*nominal is the pseudoinverse such that D*nominalDnominal is an identity matrix. This provides linear mappings from the nominal dictionary 502 to each of the other dictionaries 510, thus correcting for B1.

Because the previously acquired B1 may have a discretization that is finer in granularity than the previously generated dictionary, the values of the B1 map can be used to determine a linear mapping via a linear combination or interpolation of the computed Xtarget mappings. This linear combination may be given by:

$${X}_{target} = w {X}_{lower} + ( 1 - w ) {X}_{h i g h e r} \qquad ( Equation 3 )$$

where w is a relative distance to a higher B1 value. For example, where B1=1.45 and only B1=1.3 and B1=1.5 mappings are available would have

$$w = \frac{( 1.5 - 1.45 )}{( 1.5 - 1.3 )} = \frac{0.05}{0.25} = 0.25 ,$$

and 1−w=0.75. This relationship can also be written as:

$${D}_{target} \approx w ( {D}_{nominal} {X}_{lower} ) + ( 1 - w ) ( {D}_{nominal} {X}_{upper} ) \qquad ( Equation 4 )$$

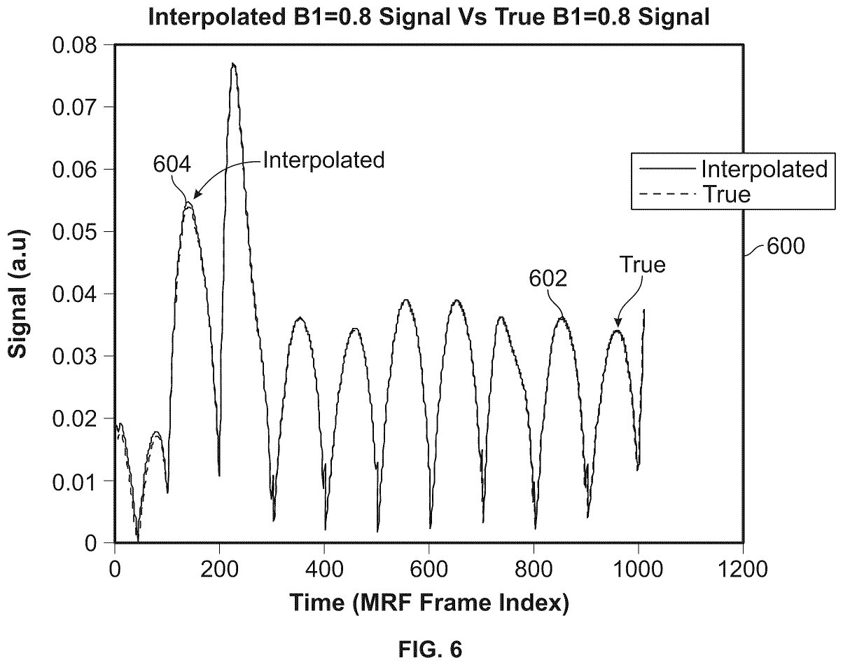

In embodiments, the change in mapping values within the X transformation matrices with respect to B1 may not be linear as assumed in the above description. In the case that such a linear relationship does not hold, errors may be observed. For example, FIG. 6 depicts errors that may result from such linear interpolation approximation. In this regard, FIG. 6 illustrates a chart 600 including a first plot 602 indicating a true B1=0.8 signal, and a second plot 604 indicating an interpolated B1=0.8 signal.

In this manner, embodiments may utilize another interpolating function rather than linear interpolation, such as a piecewise polynomial spline. The appropriateness of a specific interpolation approach may depend on the accuracy required for an application, the choice in MRF acquisition settings, MRI system hardware specifications, and/or tissue properties being modeled in an MRF dictionary, such as the target dictionary 514 depicted in FIG. 5. Alternatively still, the linear mapping of the closest of the B1 values 512 may simply be used rather than an interpolation or combination of mappings.

In an executed embodiment of the method 300, a simulation experiment was carried out using a Bloch simulation for an MRF sequence with varied flip angle, constant repetition time, and preparation pulses including inversion, T2 preparation, and T1rho preparation pulses. The full nominal dictionary used in the experiment contained 23,320 different parameter combinations with 1,009 time points for B1=1. The dictionary was subsampled to contain 2,280 parameter combinations with 1,009 time points. B1 correction dictionaries were generated for B1=0.7, 0.8, 0.9, 1.1, 1.2, and 1.3 with the same size as a corresponding nominal subsampled dictionary. Linear mapping was computed from B1=1 to each of the target B1 dictionaries. A test signal with T1=1919 ms, T2=23.5 ms, and T1rho=23.8 ms (at 500 Hz spin lock frequency) was evaluated at B1=0.8 to determine the accuracy of a linear mapped B1=0.8 correction for MRF versus a simulated ground truth B1=0.8 signal. Error of the linear mapped B1=0.8 was assessed by taking the sum of squared absolute differences between MRF time-domain signals. All plots and quantitative comparisons use signals that were normalized as they would have been for inner product based pattern matching in usual MRF reconstruction.

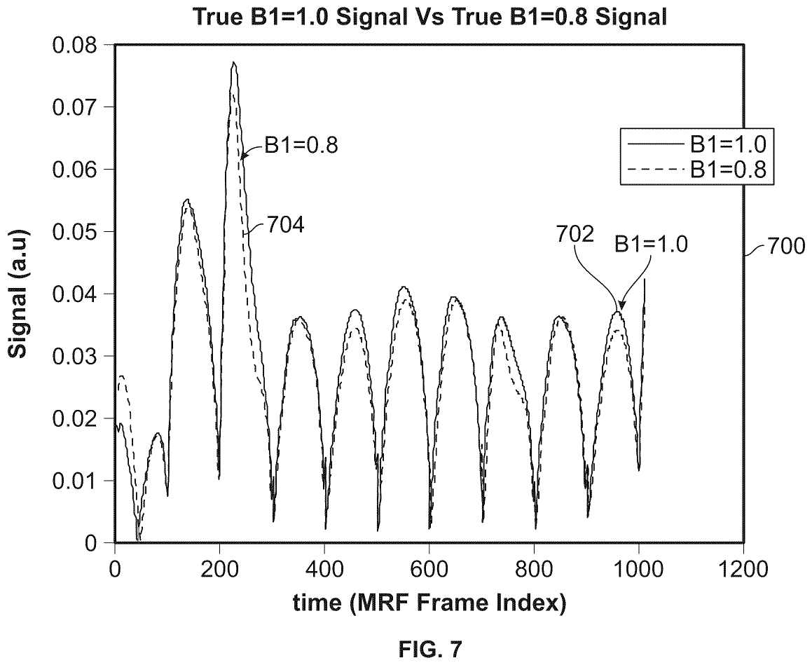

FIG. 7 is a chart 700 including a first plot 702 of the B1=1 signal, and a second plot 704 of the B1=0.8 signal from the simulation experiment without any correction, which has a sum of squared absolute errors of 1.3×10⁻². In contrast, FIG. 6 shows the signal corrected for B1 using the method 300. Notably, the mapping of B1=1 to B1=0.8 was not directly known and was determined by a weighted combination of X_{B1=0.7} and X_{B1=0.9} mappings by interpolation. As compared to FIG. 7, FIG. 6 illustrates closer agreement with the ground truth B1=0.8, and a smaller error of 2.5×10⁻⁴. Thus, the linear mapping technique of the method 300 provided a 98.2% reduction in error from an uncorrected technique.

The simulation experiment also demonstrated memory reduction using the method 300. The full dictionary had 22,320 entries, and the subsampled dictionary had 2,280 entries. Six additional small dictionaries were generated for this correction, where B1=0.7; 0.1; and 1.3 respectively. If the generated small dictionaries were full dictionaries, a total size of the dictionary would have had 156,240 entries. The implementation of the method 300, however, had one full dictionary (22,320 entries), the B1 correction small dictionaries (13,680 entries), and storage of the linear mapping values for each B1 correction dictionary (6,054 entries), for a total of 42,054 entries. For each entry having 1,009 time points, the size of the linear matching B1 correction is 27% of the size of the full dictionary B1 correction case. Assuming 8 bytes per value, the linear mapping B1 correction is 0.3 GB, where the full dictionary for the B1 correction case is 1.2 GB. In this manner, the method 300 reduces an amount of memory required for performing the B1 correction with reduced error. Further memory reduction may be possible with further optimization of the subsampled dictionary size or the number of target B1 linear mappings.

The method 300, including the process 400 and/or the process 500 for linear mapping B1 correction in MRF, may applied in conjunction with advanced MRF image reconstruction methods. In this regard, in an embodiment of the method 300 including advanced MRF reconstruction, such as iterative low rank reconstruction, the time domain of the dictionary and measured MRF undersampled images may be first compressed, requiring less memory for interim storage. In such an embodiment, the method 300 provides a linear mapping for the uncompressed temporal signal by subsequently decompressing the low rank MRF data from the interim storage such that it goes from few, compressed images into many, uncompressed images that is relatively suitable for the B1 correction. The mapping employed in the method 300 may be applied in this decompressed domain and then the data can be re-compressed after linear mapping. In embodiments, the method 300 is applied to map the compressed dictionary instead of the compressed measured data, with the result in either case being the preservation of de-noising from advanced reconstruction while obtaining the B1 correction.

The method 300, including the process 400 and/or the process 500 for linear mapping B1 correction in MRF, may be applied in conjunction with MRF spectroscopy/spectroscopic imaging techniques. Embodiments of the method 300 that implement MRF spectroscopy or MRF spectroscopic imaging may include an assumption that B1 is homogeneous within a region where an MRF time-domain signal is being obtained. For large voxels or nonlocalized spectroscopy, this assumption may not hold. The process 400 and/or the process 500 for linear mapping method for B1 correction in MRF could be applied to the dictionary for each spatial location where tissue signal is being collected, and then take the average of the dictionary generated from this approach. For example, if a large voxel for single voxel spectroscopy MRF was collected that contained 64 voxels from a reference B1 map, the correction could be applied for each voxel to generate 64B1 corrected dictionaries, which are then averaged together.

If B1 is homogeneous and with value B1=1, this would yield the same result as the nominal case with no correction, but if B1 is heterogeneous, the resultant dictionary would differ from the nominal uncorrected case. While use of a mean B1 value across the region could generally provide improvements and may be suitable for most cases, the nonuniform B1 correction approach yields a different result. For example, in a case where one voxel has B1=0.7, a second voxel has B1=0.8, and a third voxel has B1=0.9, the mean B1 value across the three voxels is B1=0.8. When plotting the averaged signal based on dictionaries simulated at their respective B1 values, a difference can be observed between the uniform B1 assumption and the nonuniform case, indicating a difference in signal even without approximations from the method 300, including linear mapping B1 correction in the process 400 and/or the process 500. Using the linear mapping B1 correction with an assumed uniform B1=0.8 gives an error of 9.3×10⁻⁵, which is reduced by 95% when the nonuniform B1 values are used to an error of 4.6×10⁻⁶. Thus, it is anticipated that inclusion of B1 correction in MRF spectroscopy could lead to improved results.

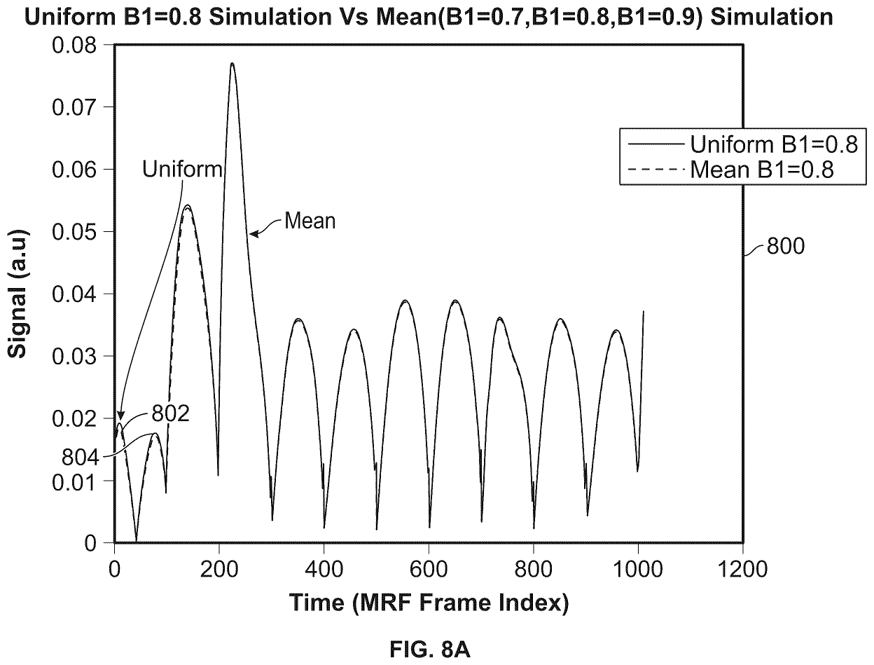

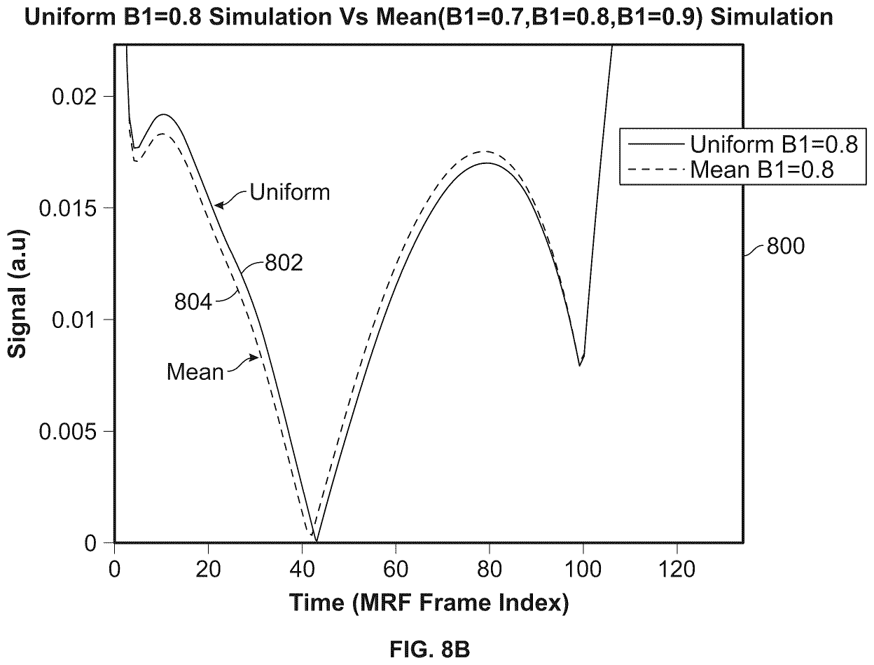

FIGS. 8A and 8B show a comparison of MRF signals at uniform B1=0.8 and nonuniform B1 with mean B1=0.8, where both signals are generated from dictionaries without use of the linear mapping B1 correction. The full signals are shown in FIG. 8A, which is a plot 800 that includes a first curve 802 that indicates the uniform B1=0.8 signal, and includes a second curve 804 that indicates the nonuniform B1 signal with mean B1=0.8.

A zoomed in portion of the first curve 802 and the second curve 804 is shown in FIG. 8B. In the uniform B1 case, a single signal from a dictionary with B1=0.8 is used. In the nonuniform B1 case indicated by the first curve 802, three signals are averaged together with B1=0.7, B1=0.8, and B1=0.9. While the signals are very similar, there are differences, demonstrating that mean B1 does not completely account for MRF signal temporal characteristics that can occur in a nonuniform B1 field.

Any aspect of the above disclosure may be implemented by a processor of an MRI scanner, or by a processor of a separate computing device(s). It is further noted than any aspect may be executed locally (e.g., at the site of the MRI scanner or of the MRI imaging), or remotely. For example, MR data acquisition may be performed locally to the MRI system at a hospital or like clinical location, while other aspects of the present disclosure are performed at a remote central processing location and at a different time than the data acquisition. Still further, it is noted that the various aspects of the present disclosure may be distributed across any number of processors and/or computing systems.

It is noted that the B1 correction and linear mapping is unique to each dictionary and thus the corresponding MRI scanner. Thus, should portions of the present disclosure be performed remote from the MRI scanner, the dictionary and mappings may be stored with information associating them with the corresponding MRI scanner. Accordingly, a single remote processor(s) may be used to implement any or all of the present disclosure for a plurality of dictionaries and/or MRI scanners.

While various features are presented above, it should be understood that the features may be used singly or in any combination thereof. Further, it should be understood that variations and modifications may occur to those skilled in the art to which the claimed examples pertain.

What is claimed is:

1. A magnetic resonance fingerprint (MRF) method comprising:
obtaining an MRF undersampled image;
determining a corresponding radiofrequency transmit magnetic field strength for a pixel of the image;
obtaining a tissue property from an MRF dictionary based on the pixel; and
correcting the tissue property based on the determined radiofrequency transmit magnetic field strength.

2. The MRF method of claim 1, wherein correcting the tissue property comprises:
linearly mapping the tissue property from the MRF dictionary to at least one corrected MRF dictionary; and
obtaining the corrected tissue property from the at least one corrected MRF dictionary.

3. The MRF method of claim 2, wherein linearly mapping the tissue property comprises linearly interpolating the corrected tissue property from a plurality of corrected MRF dictionaries.

4. The method of claim 1, further comprising determining the MRF dictionary, including generating tissue-specific signal evolutions.

5. The method of claim 4, wherein the signal evolutions are generated from a physics-based model of tissue relaxation and excitation dynamics having a homogeneous radiofrequency transmit magnetic field.

6. The method of claim 1, further comprising determining the MRF dictionary, including:
subsampling a nominal MRF dictionary;
generating the MRF dictionary as an additional MRF dictionary having a different radiofrequency transmit magnetic field strength from the nominal MRF dictionary, using a same set of tissue parameter combinations included in the nominal MRF dictionary;
computing a linear transformation matrix from the nominal MRF dictionary to the additional dictionary; and
obtaining a corrected dictionary value by interpolating from the computed linear transformation matrix.

7. The method of claim 6, further comprising:
generating a plurality of additional MRF dictionaries, including the additional MRF dictionary, using a same set of tissue parameter combinations included in the nominal MRF dictionary, based on the subsampling of the nominal dictionary, wherein each of the additional MRF dictionaries are generated at a radiofrequency transmit magnetic field strength different from each other; and
computing linear transformation matrices, including the linear transformation matrix, from the nominal MRF dictionary to each of the additional dictionaries,
wherein obtaining the corrected dictionary value includes interpolating between the linear transformation matrices and obtaining corrected dictionary values for B1 values detected during an image reconstruction.

8. The method of claim 7, wherein the nominal MRF dictionary is generated at a nominal radiofrequency transmit magnetic field strength corresponding to a B1 value of 1, and each of the additional MRF dictionaries is generated at a radiofrequency transmit magnetic field strength that differs from the radiofrequency transmit magnetic field strength of every other additional MRF dictionary by at least 0.1.

9. The method of claim 7, wherein the nominal MRF dictionary is generated at a nominal radiofrequency transmit magnetic field strength corresponding to a B1 value of 1, and the plurality of additional MRF dictionaries are generated at radiofrequency transmit magnetic field strengths corresponding to B1 values spanning an overall range from at least 0.5 to 1.5.

10. The method of claim 6, wherein computing the linear transformation matrix from the nominal MRF dictionary to the additional MRF dictionary includes performing a pseudoinversion of the subsampled nominal MRF dictionary and multiplying the pseudoinversion by the additional MRF dictionary.

11. The method of claim 1, wherein correcting the tissue property based on the determined radiofrequency transmit magnetic field strength includes generating a corrected MRF dictionary for the pixel by interpolating between entries of a nominal MRF dictionary and one or more additional MRF dictionaries corresponding to different radiofrequency transmit magnetic field strengths, wherein the interpolation between entries is performed using a piecewise polynomial spline.

12. The method of claim 11, further comprising:
assessing an error between an MRF time-domain signal generated by linear interpolation of the MRF dictionary and a true MRF time-domain signal at the radiofrequency transmit magnetic field strength of the pixel;
comparing the assessed error to a predetermined threshold;
when the assessed error is below the predetermined threshold, obtaining the corrected tissue property for the pixel by applying linear interpolation between entries of the nominal MRF dictionary and the one or more additional MRF dictionaries; and
when the assessed error exceeds the predetermined threshold, obtaining the corrected tissue property for the pixel by applying piecewise polynomial spline interpolation between entries of the nominal MRF dictionary and the one or more additional MRF dictionaries.

13. The method of claim 1, further comprising:
compressing a time domain of the MRF dictionary during interim storage;
decompressing the MRF dictionary to obtain uncompressed temporal signals corresponding to the pixel; and
applying a linear mapping for B1 correction to the uncompressed temporal signals.

14. The method of claim 1, further comprising:
compressing a time domain of the MRF dictionary during interim storage; and
applying a linear mapping for B1 correction to the compressed MRF dictionary.

15. The method of claim 1, further comprising applying a linear mapping to the MRF dictionary at each spatial location within a region based on a corresponding radiofrequency transmit magnetic field strength, and generating an averaged MRF dictionary for the region by averaging B1-corrected dictionaries from each spatial location within the region.

16. A magnetic resonance fingerprint (MRF) method comprising:
generating a full MRF dictionary based on a nominal radiofrequency transmit magnetic field strength;
for each of a plurality of radiofrequency transmit magnetic field strengths different than the nominal field strength, subsampling the full MRF dictionary and generating a corrected MRF dictionary based on the subsampled dictionary and the different field strengths; and
determining a transformation matrix between the full MRF dictionary and each of the corrected MRF dictionaries.

17. The method of claim 16, wherein the full MRF dictionary is generated at a nominal radiofrequency transmit magnetic field strength corresponding to a B1 value of 1, and each of the corrected MRF dictionaries is generated at a radiofrequency transmit magnetic field strength that differs from the radiofrequency transmit magnetic field strength of every other corrected MRF dictionary by at least 0.1, with the corrected MRF dictionaries corresponding to B1 values spanning an overall range from at least 0.5 to 1.5.

18. The method of claim 16, further comprising correcting a tissue property for a pixel by interpolating between the corrected MRF dictionaries generated at different radiofrequency transmit magnetic field strengths, based on the determined radiofrequency transmit magnetic field strength for the pixel.

19. The method of claim 18, wherein the interpolation between corrected MRF dictionaries is linear interpolation or piecewise polynomial spline interpolation based on an assessed error between an MRF time-domain signal generated by linear interpolation of the MRF dictionary and a true MRF time-domain signal at the radiofrequency transmit magnetic field strength of the pixel, compared to a predetermined threshold.

20. The method of claim 16, further comprising storing each transformation matrix between the full MRF dictionary and the corrected MRF dictionaries in a memory, and generating interpolated MRF dictionary values for arbitrary radiofrequency transmit magnetic field strengths encountered during image reconstruction using one or more of each transformation matrix stored in the memory.
